(19) United States
(12) Patent Application Publication
(10) Pub. No.: US 2025/0384915 A1
(43) Pub. Date: Dec. 18, 2025

(54) MEMORY DEVICE AND OPERATING METHOD THEREOF

(71) Applicant: Samsung Electronics Co., Ltd., Suwon-si (KR)

(72) Inventors: Seung Ki HONG, Suwon-si (KR); Jung Uk KIM, Suwon-si (KR); HOON SHIN, Suwon-si (KR); Jong Moon CHOI, Suwon-si (KR); KI-HEUNG KIM, Suwon-si (KR); Ho Seok SEOL, Suwon-si (KR); Chang Sik YOO, Suwon-si (KR); Won Ho CHOI, Suwon-si (KR); Jin Yong CHOI, Suwon-si (KR)

(21) Appl. No.: 19/207,535

(22) Filed: May 14, 2025

(30) Foreign Application Priority Data
Jun. 18, 2024 (KR) 10-2024-0079232

(51) Int. Cl. G11C 11/4078; H01L 25/065; H01L 25/18; H10B 80/00

(52) U.S. Cl. CPC G11C 11/4078; H01L 25/0657; H01L 25/18; H10B 80/00; H01L 2225/06513; H01L 2225/06517; H01L 2225/06541

(57) ABSTRACT

A memory device is provided. A memory device comprises a memory cell array including a wordline, master signal logic configured to generate a first address signal in response to the wordline being selected based on a refresh command or an active command, and to generate a second address signal in response to the wordline being selected based on a precharge command and count logic configured to reset a count value of a count cell connected to the wordline based on a paper signal generated in response to the wordline being selected based on the first address signal and the refresh command, and to read and then update the count value of the count cell based on the second address signal.

### CROSS-REFERENCE TO RELATED APPLICATION

This application claims priority under 35 U.S.C. § 119 from Korean Patent Application No. 10-2024-0079232, filed on Jun. 18, 2024, in the Korean Intellectual Property Office, and all the benefits accruing therefrom under 35 U.S.C. § 119, the contents of which in its entirety are herein incorporated by reference.

### BACKGROUND

### 1. Field

The present disclosure relates to a semiconductor memory device and an operating method thereof.

### 1. Description of the Related Art

As the integration density of memory increases, the spacing between the wordlines included in the memory is decreasing. Consequently, as the spacing between the wordlines decreases, the coupling effect between adjacent wordlines increases.

Meanwhile, when data is input or output from the memory cells, the wordlines toggle between an active state and an inactive state. As mentioned earlier, as the coupling effect between adjacent wordlines increases, data corruption in memory cells connected to wordlines adjacent to frequently activated wordlines occurs. This phenomenon, known as row hammering, is problematic because it causes data corruption in memory cells before they can be refreshed due to wordline disturbance.

### SUMMARY

Aspects of the present disclosure provide a memory device with improved reliability.

Aspects of the present disclosure also provide an operating method of a memory device with improved reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a memory device comprising a memory cell array including a wordline, master signal logic configured to generate a first address signal in response to the wordline being selected based on a refresh command or an active command, and to generate a second address signal in response to the wordline being selected based on a precharge command and count logic configured to reset a count value of a count cell connected to the wordline based on a paper signal generated in response to the wordline being selected based on the first address signal and the refresh command, and to read and then update the count value of the count cell based on the second address signal.

According to the aforementioned and other embodiments of the present disclosure, a memory device comprising a memory cell array including a wordline, a multiplexer configured to receive a paper signal having a first logic level in response to the wordline being selected based on a refresh command, and output a first signal in response to receiving the paper signal having the first logic level, and to receive a paper signal having a second logic level different from the first logic level in response to the wordline being selected based on an active command, and output a second signal and an updater configured to reset a count value of a count cell connected to the wordline in response to receipt of the first signal, and to update the count value of the count cell in response to receipt of the second signal, wherein the first signal is generated based on a first address signal having the first logic level in response to the wordline being selected based on the refresh command or the active command, the first signal has the first logic level after a lapse of a first period from a transition of the first address signal to the first logic level, the second signal is generated based on a bank activation signal and a second address signal, the bank activation signal has the first logic level in response to the wordline being selected based on the refresh command or the active command, and the second address signal has the first logic level in response to the wordline being selected based on a precharge command.

According to the aforementioned and other embodiments of the present disclosure, an operating method of a memory device, comprising in response to receipt of an active command for a wordline, transitioning a first address signal representing an address of the wordline to a first logic level, in response to the transition of the first address signal to the first logic level, transitioning a first signal indicating that a bank for the wordline is being activated to the first logic level, in response to receipt of a precharge command for the wordline after a lapse of a first period from the receipt of the active command, performing a first transition that transitions a second address signal representing the address of the wordline to the first logic level, in response to the first transition, reading a first count value of a count cell included in the wordline, writing a second count value obtained by adding an update value to the first count value to the count cell, generating a second signal for controlling a precharge operation for the wordline after a lapse of a second period from the receipt of the precharge command, in response to the generation of the second signal, performing a second transition that transitions the second address signal to the first logic level and in response to the second transition, transitioning the first signal to a second logic level different from the first logic level.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a block diagram illustrating a memory system according to some embodiments of the present disclosure.

FIGS. 2 and 3 are block diagrams illustrating an exemplary memory device included in the memory system of FIG. 1.

FIG. 4 is a circuit diagram illustrating an exemplary memory cell array included in the memory device of FIG. 3.

FIG. 5 is a block diagram illustrating an exemplary master signal logic and count logic included in the memory device of FIG. 3.

FIG. 6 is a circuit diagram detailing the block diagram of FIG. 5.

FIG. 7 is a timing diagram for explaining the circuit diagram of FIG. 6.

FIGS. 8 through 11 are circuit diagrams for explaining the circuit diagram of FIG. 6.

FIG. 12 is a timing diagram for explaining the circuit diagram of FIG. 6.

FIG. 13 is a circuit diagram for explaining the circuit diagram of FIG. 6.

FIG. 14 is a circuit diagram for explaining the circuit diagram of FIG. 6.

FIG. 15 is a timing diagram for explaining the circuit diagram of FIG. 6.

FIGS. 16 through 19 are circuit diagrams for explaining the circuit diagram of FIG. 6.

FIGS. 20 and 21 are flowcharts for explaining the operation of the memory device of FIG. 6.

FIG. 22 is a block diagram illustrating a stacked memory device according to some embodiments of the present disclosure.

FIG. 23 is a block diagram of the stacked memory device of FIG. 22.

FIG. 24 is a block diagram illustrating an exemplary buffer die of FIG. 23.

FIG. 25 is a diagram illustrating a semiconductor package according to some embodiments of the present disclosure.

FIG. 26 is a diagram illustrating an exemplary implementation of a semiconductor package according to an embodiment of the present disclosure.

FIG. 27 is a diagram illustrating a semiconductor package according to some embodiments of the present disclosure.

### DETAILED DESCRIPTION

Embodiments of the present disclosure will hereinafter be described in detail with reference to the accompanying drawings. The same reference numerals are used for the same components in the drawings, and redundant descriptions thereof will be omitted.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

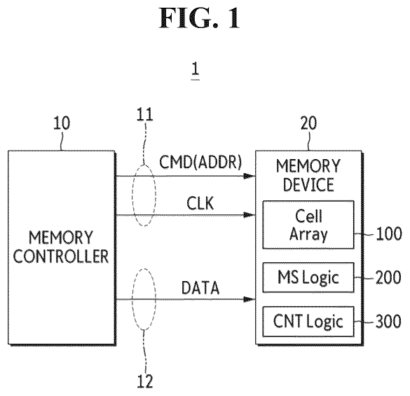

FIG. 1 is a block diagram illustrating a memory system according to some example embodiments of the present disclosure.

Referring to FIG. 1, a memory system 1 includes a memory controller 10 and a memory device 20. Each of the memory controller 10 and the memory device 20 includes an interface for mutual communication. These interfaces may be connected through a control bus 11 for transmitting commands CMD, addresses ADDR, clock signals CLK, etc., and a data bus 12 for transmitting data DATA. The commands CMD may be considered to include the addresses ADDR.

The memory controller 10 generates the commands CMD to control the memory device 20, and under the control of the memory controller 10, the data DATA may be written to or read from the memory device 20. The memory device 20 may transmit data read from memory cells, status information of the memory device 20, etc., through the data bus 12.

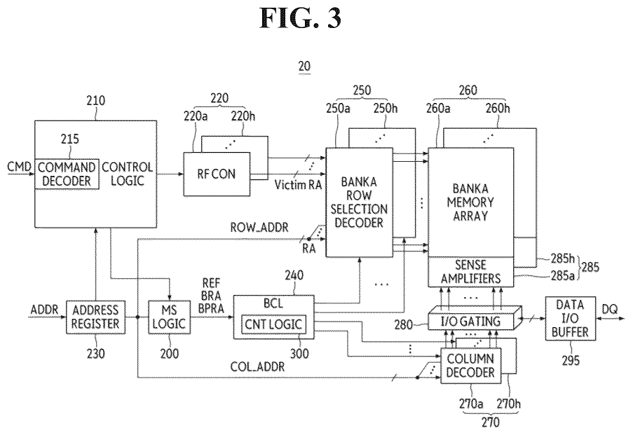

In some embodiments, the memory device 20 may include a memory cell array 100 for storing data, master signal logic (“MS LOGIC”) 200 for providing addresses ADDR to count logics (“CNT LOGIC”) 300, and the count logics 300 for storing values in count cells within a bank memory array (e.g., bank memory array 260 in FIG. 3).

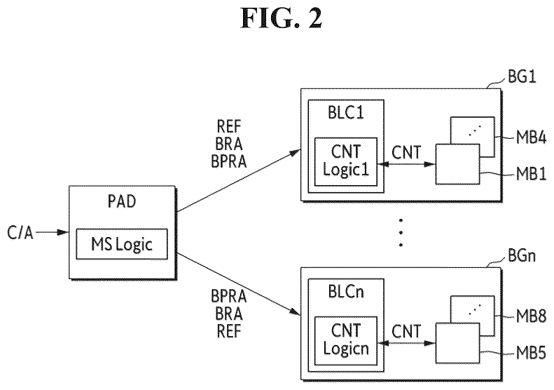

FIGS. 2 and 3 are block diagrams illustrating an exemplary memory device included in the memory system of FIG. 1.

Referring to FIG. 2, the memory device 20 may include a pad PAD and a plurality of bank groups BG1 through BGn.

The pad PAD may include the master signal logic MS LOGIC.

The bank groups BG1 through BGn may include bank control logics BCL1 through BCLn, respectively, and a plurality of bank memories MB1 through MB8. Each of the bank control logics BCL1 through BCLn may include count logics CNT LOGIC1 through CNT LOGICn, respectively. The master signal logic MS LOGIC, which receives command/address signals C/A, may provide refresh signals REF, address signals BRA, and precharge address signals BPRA to the count logics CNT LOGIC1 through CNT LOGICn.

The count logics CNT LOGIC1 through CNT LOGICn may read count values CNT stored in the bank memories MB1 through MB8 within the respective bank groups BG1 through BGn, or write new count values CNT to the bank memories MB1 through MB8.

FIG. 3 illustrates one of the bank groups of FIG. 2, for example, the bank group BG1. Referring to FIG. 3, the memory device 20 may include master signal logic (“MS LOGIC”) 200, memory control logic 210, an address register 230, bank control logic (BCL) 240, a row selection circuit 250, a column decoder 270, a bank memory array 260, sense amplifiers 285, an input/output (I/O) gating circuit 280, a data I/O buffer 295, and a refresh controller unit (“RF CON”) 220.

The bank memory array 260 may include a plurality of bank memories 260a through 260h. The row selection circuit 250 may include a plurality of bank row selection circuits 250a through 250h, which are connected to the bank memories 260a through 260h, respectively. The column decoder 270 may include a plurality of bank column decoders 270a through 270h, which are connected to the bank memories 260a through 260h, respectively. The sense amplifier unit 285 may include a plurality of sense amplifiers 285a through 285h, which are connected to the bank memories 260a through 260h, respectively.

Each of the bank memories 260a through 260h may include a plurality of memory blocks. Each of the memory blocks may include a plurality of memory cells. The memory cell array 100 may include a plurality of memory cells. For example, the memory cells may be dynamic random-access memory (DRAM) cells. In this example, the memory interface may communicate based on one of the following standards: Double Data Rate (DDR), Low Power DDR (LPDDR), Graphics Double Data Rate (GDDR), Wide I/O, High Bandwidth Memory (HBM), or Hybrid Memory Cube (HMC).

The memory device 20 may receive a command/address signal C/A based on a clock signal CK. The command/address signal C/A may include a command signal CMD and an address signal ADDR.

The address register 230 may receive address information from the memory controller 10. The address information may include a bank address BANK_ADDR, a row address ROW_ADDR, and a column address COL_ADDR. The address register 230 may convert the address information into an internal address of the memory device 20. For example, the address register 230 may provide the row address ROW_ADDR to the row selection circuit 250 and the column address COL_ADDR to the column decoder 270.

The row address ROW_ADDR output from the address register 230 may be applied to the bank row selection circuits 250a through 250h. Among the bank row selection circuits 250a through 250h, the bank row selection circuit activated by the bank control logic 240 decodes the row address ROW_ADDR and activates the corresponding wordline by applying an operating voltage. For example, the activated bank row selection circuit may apply a wordline driving voltage for the row corresponding to the row address ROW_ADDR. Specifically, the activated bank row selection circuit, for example, the bank row selection circuit 250a, may apply an activation driving voltage to a target row's wordline (e.g., the wordline corresponding to the row address ROW_ADDR) based on an active command and a refresh driving voltage to a refresh target row's wordline based on a refresh command.

The column decoder 270 may include a column address latch. The column address latch may receive the column address COL_ADDR from the address register 230 and temporarily store the received column address COL_ADDR. Additionally, in burst mode, the column address latch may gradually increment the received column address COL_ADDR. The column address latch may then apply the temporarily stored or gradually incremented column address COL_ADDR to the bank column decoders 270a through 270h.

Among the bank column decoders 270a through 270h, the bank column decoder activated by the bank control logic 240 may activate the sense amplifier corresponding to the bank address BANK_ADDR and the column address COL_ADDR through the I/O gating circuit 280.

The I/O gating circuit 280 may include circuits for gating input/output data, input data mask logic, read data latches for storing data output from the bank memories 260a through 260h, and write drivers for writing data to the bank memories 260a through 260h.

Data DQ read from one of the bank memories 260a through 260h may be sensed by the corresponding sense amplifier and may be stored in the read data latches. The data DQ stored in the read data latches may be provided to the memory controller 10 through the data I/O buffer 295. The data DQ to be written to one of the bank memories 260a through 260h may be provided to the data I/O buffer 295 from the memory controller 10. The data DQ provided to the data I/O buffer 295 may then be written to one of the bank memories 260a through 260h through the write drivers.

The refresh controller unit 220 may control the row selection circuit 250 of the memory device 20 to perform a refresh operation. For example, the refresh controller unit 220 may control the row selection circuit 250 of the memory device 20 to perform a refresh operation on one of the bank memories 260a through 260h activated by the bank control logic 240 based on an external refresh command from the memory controller 10 or an internal decision to perform a refresh operation. In some embodiments, the refresh controller unit 220 may include a plurality of refresh controllers 220a through 220h corresponding to the bank row selection circuits 250a through 250h, respectively.

In some embodiments, the refresh controller unit 220 may extract at least one victim row address Victim RA based on a target row address for an external or internal refresh operation and control the bank row selection circuit 250 to perform a refresh operation on the victim row. For example, the bank row selection circuit 250 may apply a refresh voltage to the victim row.

The memory control logic 210 may generally control the operation of the memory device 20. In some embodiments, the memory control logic 210 may generate first control signals to perform an activation operation such as a write or read operation on the memory device 20. In some embodiments, the memory control logic 210 may control the refresh controller unit 220 through refresh controller control signals to perform a refresh operation on the memory device 20.

FIG. 3 illustrates the refresh controller unit 220 and the memory control logic 210 as being separate components. In some embodiments, the refresh controller unit 220 and the memory control logic 210 may be implemented as independent components as depicted. Alternatively, in some embodiments, the memory control logic 210 may be configured to include the refresh controller unit 220.

The command decoder 215 may receive the command CMD from the command/address signal C/A and may decode the command CMD into an internal command of the memory device 20. The command decoder 215 may generate the internal command while decoding the command CMD received from the memory controller 10.

In some embodiments, when a refresh command REF_CMD is received from the memory controller 10, the memory control logic 210 may generate a refresh controller control signal for an external refresh operation.

FIG. 3 illustrates the memory control logic 210 and the address register 230 as being separate components, but the memory control logic 210 and the address register 230 may be implemented as an inseparable single component. Additionally, FIG. 3 illustrates the command CMD and the address ADDR as being separate signals provided individually, but as specified in standards such as LPDDR5, the address ADDR may be considered to be included in the command CMD.

The master signal logic 200 may receive the command/address signal C/A and output an address signal BRA, a precharge address signal BPRA, and a refresh signal REF. The address signal BRA and the precharge address signal BPRA may correspond to decoded address signals provided along with the command signal CMD. The refresh signal REF may be a signal generated in response to the provision of a refresh command. The master signal logic 200 may provide the address signal BRA, the precharge address signal BPRA, and the refresh signal REF to the count logic 300 included in the bank control logic 240, selected by the address signal BRA or the precharge address signal BPRA.

The count logic 300 may read count values CNT stored in the bank memories 260a through 260h by the bank row selection circuits 250a through 250h and the column decoders 270a through 270h, or write new count values CNT.

Through the master signal logic 200 and the count logic 300, at least one victim row address of a victim row adjacent to a wordline where active and precharge operations frequently occur may be extracted, and a row hammer refresh operation may be performed on the victim row. The number of active operations occurring on the corresponding wordline may be stored in the count cells within the bank memory array 260. The count cells will be described later in further detail.

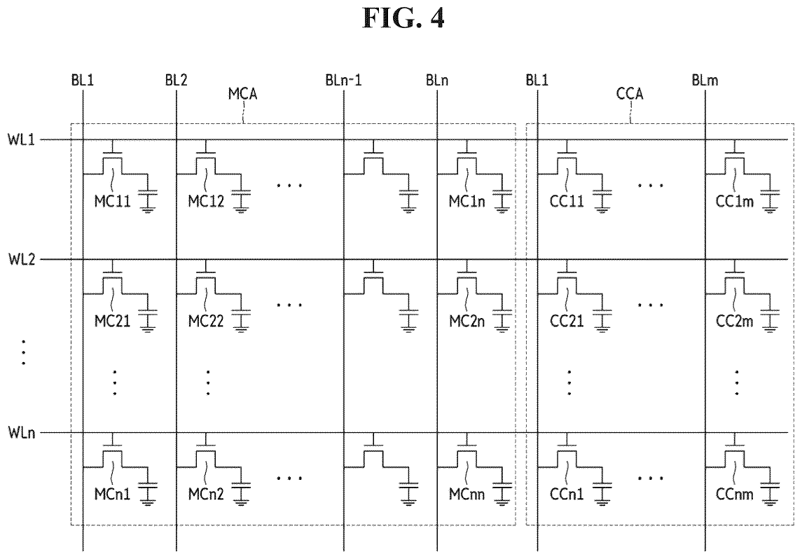

FIG. 4 is a circuit diagram illustrating an exemplary memory cell array included in the memory device of FIG. 3.

Referring to FIGS. 1, 3, and 4, the bank memory array 260 may include a memory cell group MCA and a count cell group CCA. The memory cell group MCA may include, for example, a plurality of memory cells MC11 through MCnn, which store the data DATA transmitted from the memory controller 10. The count cell group CCA may include a plurality of memory cells CC11 through CCnm, which store count values CNT based on an active or refresh command for a particular wordline within the memory device 20. For example, whenever the memory device 20 receives an active command for a first wordline WL1, count cells CC11 through CC1m connected to the first wordline WL1 may store a new count value CNT obtained by incrementing each existing count value CNT by one.

The memory cells MC11 through MCnn and the memory cells CC11 through CCnm each include one transistor and one capacitor.

The memory cells MC11 through MCnn and the memory cells CC11 through CCnm may each be connected to one wordline and one bitline. For example, the memory cell MC11 may be connected to the first wordline WL1 and a first bitline BL1. For example, the memory cell MCnn may be connected to the n-th wordline WLn and the n-th bitline BLn. Each of the memory cells MC11 through MCnn may store charge through the capacitor.

The memory cell array 100, which includes the memory cells MC11 through MCnn and the memory cells CC11 through CCnm, like those in DRAM, has multiple bank memories for storing data, and each of the bank memories contains numerous memory cells. As described above, each memory cell consists of a cell transistor acting as a switch and a cell capacitor storing data. However, due to the structural characteristics of each memory cell, such as the PN junction of the cell transistor, leakage current may occur, causing the initial data stored in the cell capacitor to be lost.

Therefore, a refresh operation to recharge the data in each memory cell before it is lost may be required.

Recently, in addition to a normal refresh operation, an additional refresh operation is performed on the memory cells of a particular wordline that are highly likely to lose data due to the row hammering phenomenon. Row hammering refers to a phenomenon where the data of the memory cells connected to the particular wordline or neighboring wordlines are damaged due to a high number of activations.

To prevent the row hammering phenomenon, an additional refresh operation may be performed on wordlines that are activated more than a predetermined number of times.

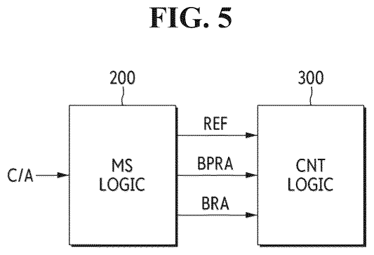

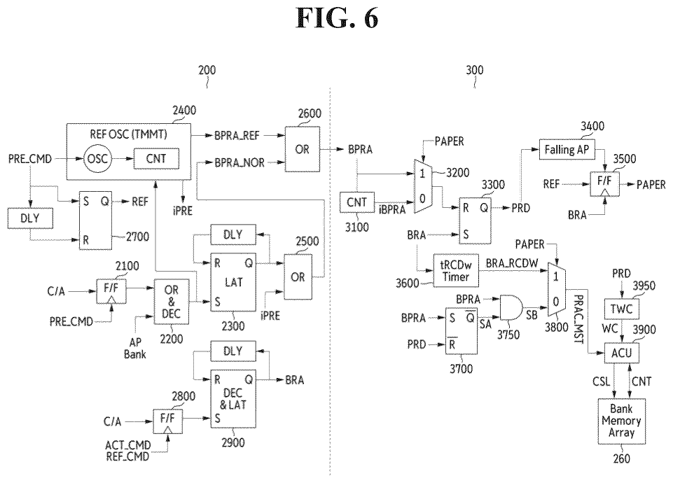

FIG. 5 is a block diagram illustrating an exemplary master signal logic and count logic included in the memory device of FIG. 3. FIG. 6 is a circuit diagram detailing the block diagram of FIG. 5.

Referring to FIGS. 5 and 6, the memory device 20 may include master signal logic (“MS LOGIC”) 200 and count logic (“CNT LOGIC”) 300. The master signal logic 200 may generate an address signal BRA and a precharge address signal BPRA based on a command/address signal C/A transmitted from the memory controller 10. The count logic 300 may generate a master signal that initiates a counting operation according to the address signal BRA and the precharge address signal BPRA received from the master signal logic 200, and may perform the counting operation accordingly.

Referring to FIG. 6, the master signal logic 200 may include a first flip-flop (“F/F”) 2800, a second flip-flop (“F/F”) 2100, a decoder (“OR & DEC”) 2200, a first latch (“DEC & LAT”) 2900, a second latch (“LAT”) 2300, a third latch 2700, a first counter (“REF OSC (TMMT)”) 2400, a first OR gate 2500, and a second OR gate 2600. The count logic 300 may include a second counter (“CNT”) 3100, a third counter (“tRCDw Timer”) 3600, a first multiplexer 3800, a second multiplexer 3200, a fourth latch 3300, a fifth latch 3700, a falling auto-pulse circuit (“Falling AP”) 3400, a third flip-flop (“F/F”) 3500, an AND gate 3750, an updater (“ACU”) 3900, and a weighted counter (“TWC”) 3950. The count logic 300 may read or write a count value CNT from or to the bank memory array 260 via a column selection line CSL.

In response to an active command ACT_CMD or a refresh command REF_CMD, the first flip-flop 2800 may transmit the command/address signal C/A as a set signal S to the first latch 2900. The first latch 2900 may output the address signal BRA using the output signal from the first flip-flop 2800 as the set signal S. The first latch 2900 may reset the address signal BRA after a predetermined delay. In response to a precharge command PRE_CMD, the second flip-flop 2100 may transmit the command/address signal C/A to the decoder 2200. The decoder 2200 may perform an OR operation on address information from an auto-precharge command and address information from a precharge command and decode and output the result of the OR operation. The output signal of the decoder 2200 may be transmitted to the first counter 2400 and become the set signal S of the second latch 2300. The second latch 2300 may output address information using the output signal from the decoder 2200 as the set signal S. The third latch 2700 may output a refresh signal REF using the refresh command REF_CMD as the set signal S. The third latch 2700 may reset the refresh signal REF after a predetermined delay. In response to the refresh command REF_CMD, the first counter 2400 may output a refresh-precharge signal BPRA_REF after a first period tRFC. In response to the output signal of the decoder 2200, the first counter 2400 may output an internal precharge signal iPRE after a third period tRP. The first OR gate 2500 may perform an OR operation on the internal precharge signal iPRE and the output signal of the second latch 2300 to output a normal-precharge signal BPRA_NOR. The second OR gate 2600 may perform an OR operation on the refresh-precharge signal BPRA_REF and the normal-precharge signal BPRA_NOR to output the precharge address signal BPRA.

The second counter 3100 may be triggered at a falling edge of the precharge address signal BPRA to output an internal precharge address signal iBPRA. In response to the input of the address signal BRA, the third counter 3600 may output a delayed address signal BRA_RCDw after a second period tRCDw. The second multiplexer 3200 may output either the precharge address signal BPRA or the internal precharge address signal iBPRA based on a paper signal PAPER. The fourth latch 3300 may output a bank activation signal PRD using the address signal BRA as the set signal S and the output signal of the second multiplexer 3200 as a reset signal R. The bank activation signal PRD may indicate that the corresponding bank is in an active state. In response to the address signal BRA and the refresh signal REF, the third flip-flop 3500 may output the paper signal PAPER. The paper signal PAPER may be deactivated after a predetermined time following the deactivation of the bank activation signal PRD by the falling auto-pulse circuit 3400. The fifth latch 3700 may output an abnormal prevention signal SA using the precharge address signal BPRA as the set signal S and the bank activation signal PRD as a reset bar signal R̅. The AND gate 3750 may perform an AND operation on the precharge address signal BPRA and the abnormal prevention signal SA to output an initial precharge address signal SB. The first multiplexer 3800 may output either the delayed address signal BRA_RCDw or the initial precharge address signal SB as a counting master signal PRAC_MST based on the paper signal PAPER. The updater 3900 may perform a counting operation in response to the counting master signal PRAC_MST. The counting operation may include resetting or updating the count values CNT stored in the bank memory array 260. The detailed operations of the components included in the master signal logic 200 and the count logic 300 will be described later.

The weighted counter 3950 is configured to compensate for the row bleed phenomenon when the active state is maintained for an extended period. The weighted counter 3950 may calculate a weighted count value WC by dividing a period “long tRAS” between the active command ACT_CMD and the precharge command PRE_CMD by the minimum required time internally specified (i.e., tRAS or tRP) between the active command ACT_CMD and the precharge command PRE_CMD. When the weighted count value WC is provided to the updater 3900, the updater 3900 may increment each count value CNT by the weighted count value WC.

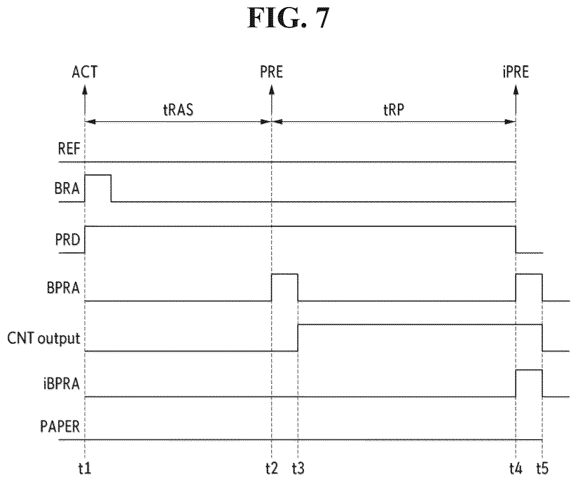

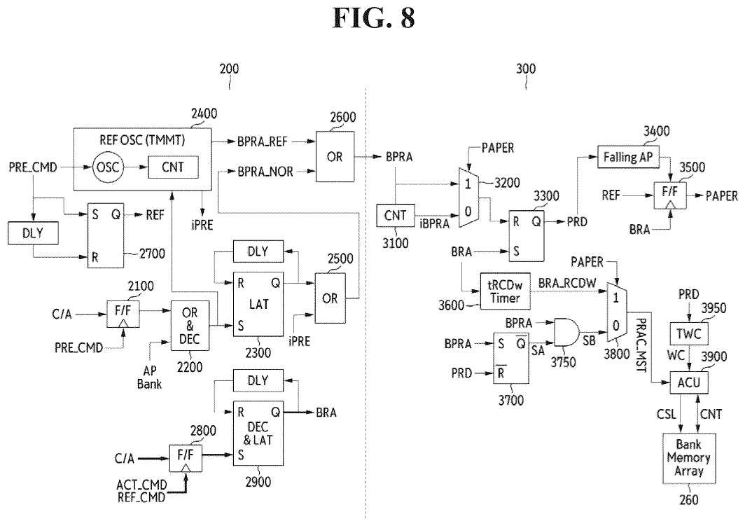

FIG. 7 is an example timing diagram for explaining the circuit diagram of FIG. 6. FIGS. 8 through 11 are circuit diagrams for explaining the circuit diagram of FIG. 6.

Referring to FIGS. 7 and 8, in response to the active command ACT_CMD being transmitted at a first time t1, the first flip-flop 2800 outputs the command/address signal C/A, and the output signal C/A becomes the set signal S of the first latch 2900, allowing the address signal BRA to have a first logic level. The first logic level may indicate a logical high state. The address signal BRA is reset after a predetermined delay, changing to a second logic level. The second logic level may indicate a logical low state.

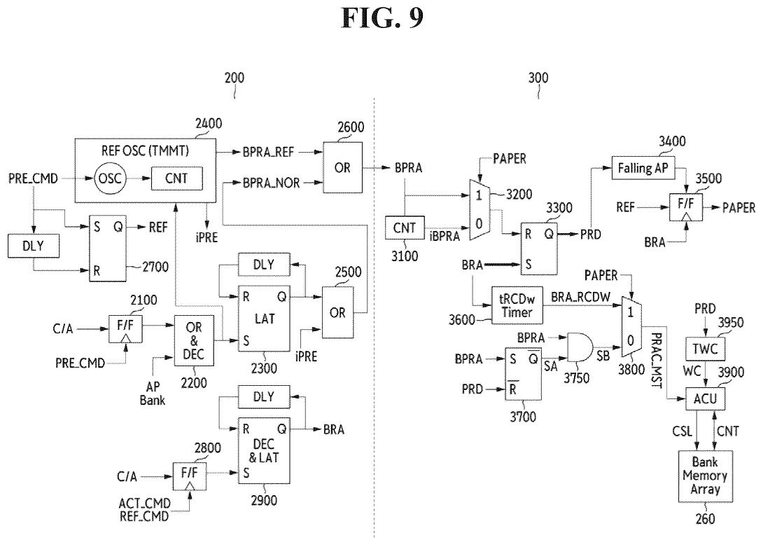

Referring to FIGS. 7 and 9, with the address signal BRA as the set signal S, the bank activation signal PRD may have the first logic level at the first time t1.

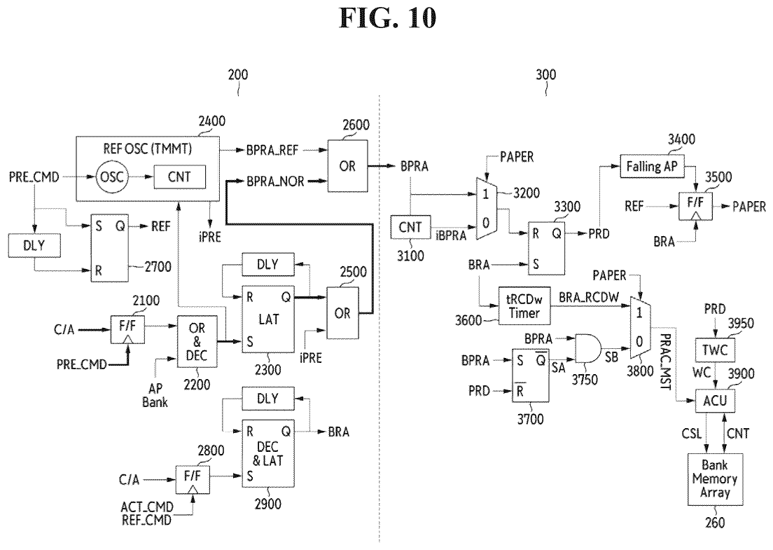

Referring to FIGS. 7 and 10, in response to the precharge command PRE_CMD being transmitted at a second time t2, the normal-precharge signal BPRA_NOR may be generated through the second flip-flop 2100, the decoder 2200, the second latch 2300, and the second OR gate 2600. The precharge command PRE_CMD may be transmitted at the second time t2, a fourth period tRAS after the first time t1 when the active command ACT_CMD is transmitted. The normal-precharge signal BPRA_NOR may be output as the precharge address signal BPRA through the second OR gate 2600. That is, in response to the precharge command PRE_CMD being transmitted at the second time t2, the precharge address signal BPRA may have the first logic level at the second time t2.

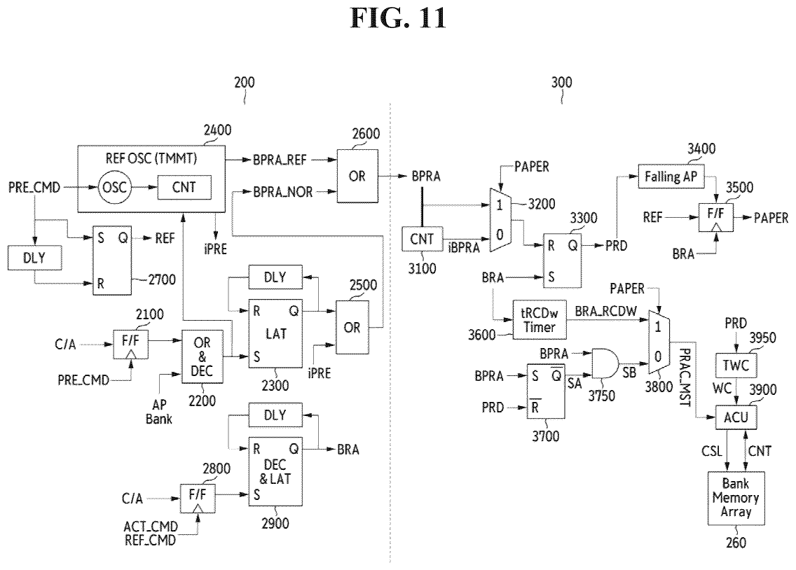

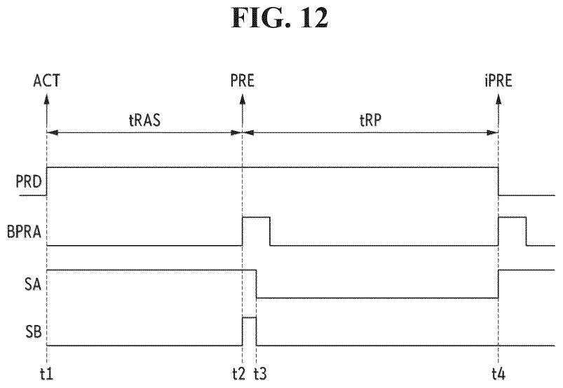

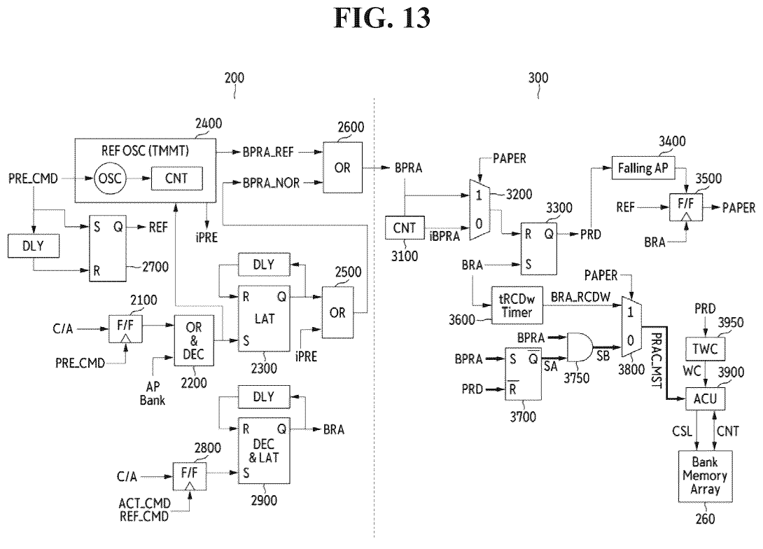

Referring to FIGS. 7 and 11, since the second counter 3100 is triggered by a falling edge of the precharge address signal BPRA, the internal precharge address signal iBPRA may have the second logic level in the period between the second time t2 and the third time t3. As the internal precharge address signal iBPRA has the second logic level, the bank activation signal PRD is not reset through the fourth latch 3300. It is evident that the paper signal PAPER, activated by the refresh signal REF, has the second logic level. Thus, even though the precharge command PRE_CMD is transmitted, the bank activation signal PRD is not reset, and no precharge operation is performed. Instead, the counting operation may be performed as illustrated in FIGS. 12 and 13, which will hereafter be described.

FIG. 12 is an example timing diagram for explaining the circuit diagram of FIG. 6. FIG. 13 is a circuit diagram for explaining the circuit diagram of FIG. 6.

Referring to FIGS. 12 and 13, with the precharge address signal BPRA as the set signal S, the fifth latch 3700 may invert and output the precharge address signal BPRA. Therefore, the abnormal prevention signal SA may have the second logic level at the third time t3, a predetermined delay after the second time t2 when the precharge address signal BPRA has the first logic level. Conversely, with the bank activation signal PRD as the reset bar signal R̅, the fifth latch 3700 may invert and output the bank activation signal PRD. Thus, in response to the bank activation signal PRD having the second logic level at the fourth time t4, the abnormal prevention signal SA may have the first logic level. That is, the abnormal prevention signal SA may have the first logic level in the period between the second time t2 and the third time t3, and the second logic level in the period between the third time t3 and the fourth time t4. Accordingly, the initial precharge address signal SB, output through an AND operation on the precharge address signal BPRA and the abnormal prevention signal SA, may have the first logic level in the period between the second time t2 and the third time t3. Since the paper signal PAPER has the second logic level, the first multiplexer may output the initial precharge address signal SB as the counting master signal PRAC_MST. In response to the counting master signal PRAC_MST, the updater 3900 may reset or update the count cells in the bank memory array 260. The operation of the updater 3900 in response to the counting master signal PRAC_MST will be described later in further detail.

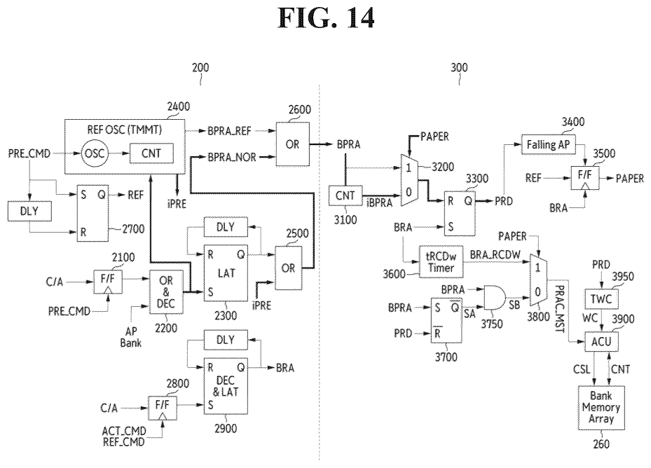

FIG. 14 is a circuit diagram for explaining the circuit diagram of FIG. 6.

Referring to FIGS. 7 and 14, in response to the precharge command PRE_CMD transmitted at the second time t2, decoded command/address information may be output by the first counter 2400 as the internal precharge signal iPRE when the third period tRP has elapsed. The internal precharge signal iPRE may be output as the precharge address signal BPRA through the first OR gate 2500 and the second OR gate 2600. Since the second counter 3100 is triggered by a falling edge of the precharge address signal BPRA, a counter output signal “CNT output” may have the first logic level in the period between the third time t3 and a fifth time t5 when the precharge address signal BPRA has the second logic level, and accordingly, the internal precharge address signal iBPRA may have the first logic level in the period between the fourth time t4 and the fifth time t5. Since the paper signal PAPER has the second logic level, the second multiplexer 3200 outputs the internal precharge address signal iBPRA. The fourth latch 3300 resets the bank activation signal PRD using the internal precharge address signal iBPRA as the reset signal. Therefore, the bank activation signal PRD has the second logic level at the fourth time t4. Accordingly, a precharge operation is performed. That is, the actual precharge operation is performed when the third period tRP has elapsed since the receipt of the precharge command PRE_CMD. This ensures time to update the count values CNT in the bank memory array 260 while properly performing the precharge operation.

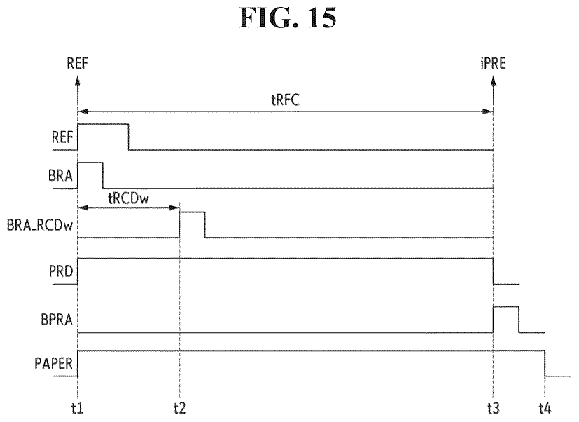

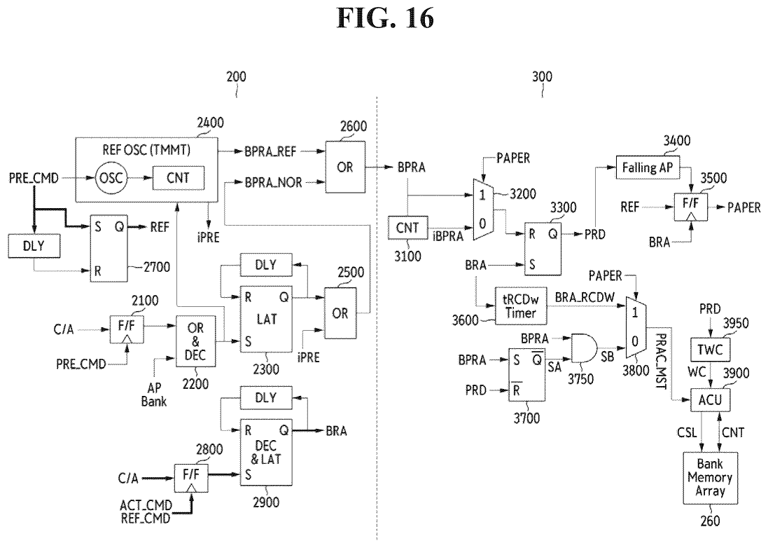

FIG. 15 is an example timing diagram for explaining the circuit diagram of FIG. 6. FIGS. 16 through 19 are circuit diagrams for explaining the circuit diagram of FIG. 6.

Referring to FIGS. 15 and 16, in response to the refresh command REF_CMD being transmitted at the first time t1, the first flip-flop 2800 outputs the command/address signal C/A, and the output signal C/A becomes the set signal S of the first latch 2900, allowing the address signal BRA to have the first logic level. The address signal BRA is reset after a predetermined delay, changing to the second logic level. Additionally, due to the third latch 2700 using the refresh command REF_CMD, transmitted at the first time t1, as the set signal S, the refresh signal REF may have the first logic level at the first time t1.

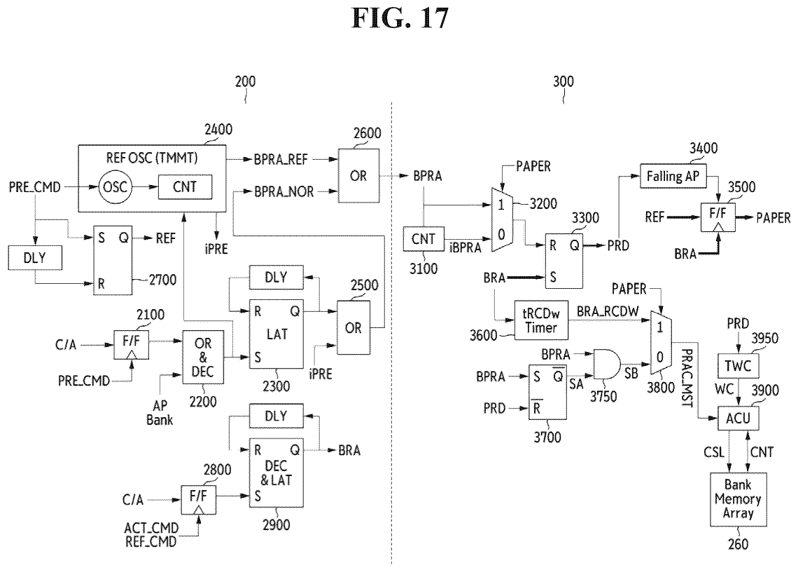

Referring to FIGS. 15 and 17, the address signal BRA and the refresh signal REF output from the master signal logic 200 may be input to the set signal S of the fourth latch 3300 and the third flip-flop 3500. The fourth latch 3300 may output the bank activation signal PRD using the address signal BRA as the set signal S at the first time t1. Additionally, as the bank address signal BRA is activated, the third flip-flop 3500 may output the refresh signal REF and generate the paper signal PAPER. For example, in response to the address signal BRA and the refresh signal REF being activated at the first time t1, the paper signal PAPER may have the first logic level.

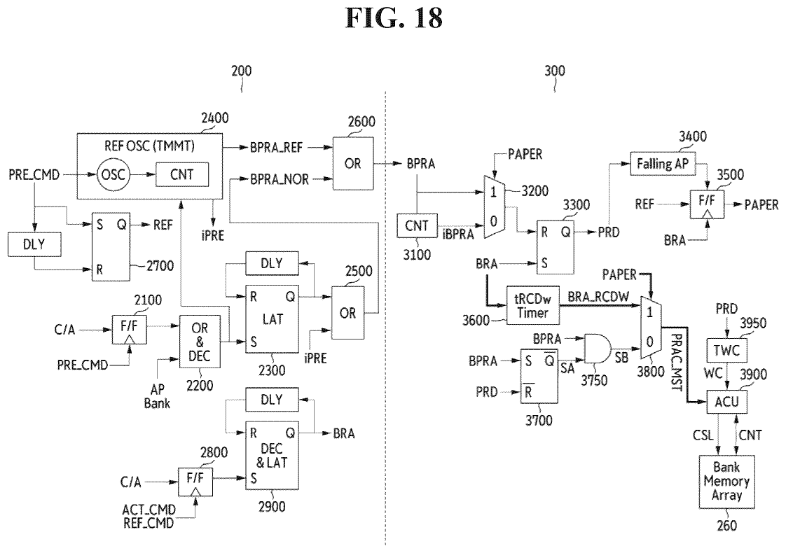

Referring to FIGS. 15 and 18, in response to the address signal BRA, output from the master signal logic 200, being input to the third counter 3600, the delayed address signal BRA_RCDw may be output after the second period tRCDw. For example, in response to the address signal BRA having the first logic level at the first time t1, the delayed address signal BRA_RCDw may have the first logic level at the second time t2 after the lapse of the second period tRCDw. Additionally, in response to the paper signal PAPER with the first logic level, output from the third flip-flop 3500, being input to the first multiplexer 3800, the first multiplexer 3800 may output the delayed address signal BRA_RCDw to generate the counting master signal PRAC_MST. The updater 3900 may reset or update the count cells in the bank memory array 260 in response to the counting master signal PRAC_MST. The operation of the updater 3900 in response to the counting master signal PRAC_MST will be described later in further detail. Since a refresh operation also includes an active operation and a precharge operation, accurate counting is required during the refresh operation to ensure the reliability of a row hammer precharge operation. However, in the case of the refresh operation, an additional refresh operation is not needed for the corresponding wordline, and thus, the count values CNT can be reset regardless of the existing count values CNT. Therefore, the updater 3900 may perform a reset operation at the second time t2 after the lapse of the second period tRCDw, which allows a write operation for the corresponding wordline.

During the active operation, the counting master signal PRAC_MST may be generated after the fourth period tRAS has elapsed since the receipt of the active command ACT_CMD. During the refresh operation, the counting master signal PRAC_MST may be generated after the second period tRCDw has elapsed from the receipt of the refresh command REF_CMD. That is, the counting master signal PRAC_MST may differ depending on the active operation or the refresh operation. Additionally, the second period tRCDw may be shorter than the fourth period tRAS. That is, the time to perform the counting operation may differ depending on the active operation or the refresh operation.

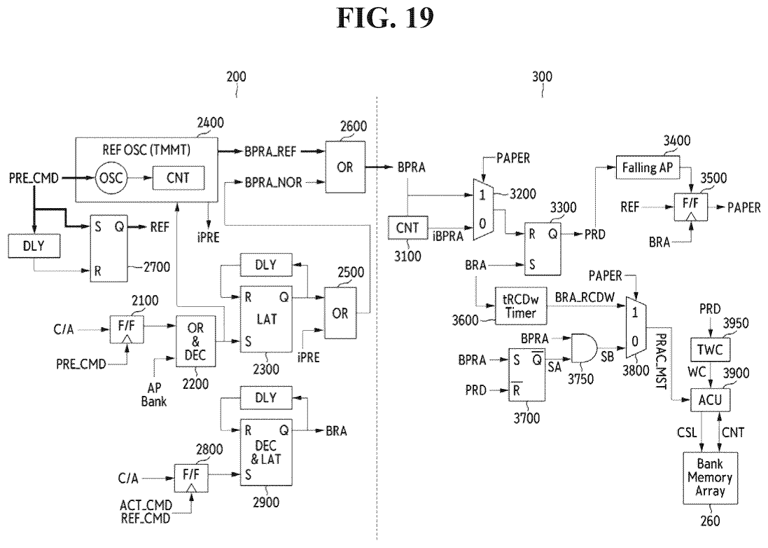

Referring to FIGS. 15 and 19, in response to the refresh command REF_CMD being transmitted at the first time t1, the first counter 2400 may output the refresh-precharge signal BPRA_REF at the third time t3 after the lapse of the first period tRFC. The refresh-precharge signal BPRA_REF may be output as the precharge address signal BPRA by the second OR gate 2600. The precharge address signal BPRA may be input to the second multiplexer 3200 and output by the paper signal PAPER. The precharge address signal BPRA output through the second multiplexer 3200 may be input as the reset signal R of the fourth latch 3300 to reset the bank activation signal PRD. For example, in response to the precharge address signal BPRA having the first logic level at the third time t3, the bank activation signal PRD may have the second logic level. Accordingly, the precharge operation may be performed.

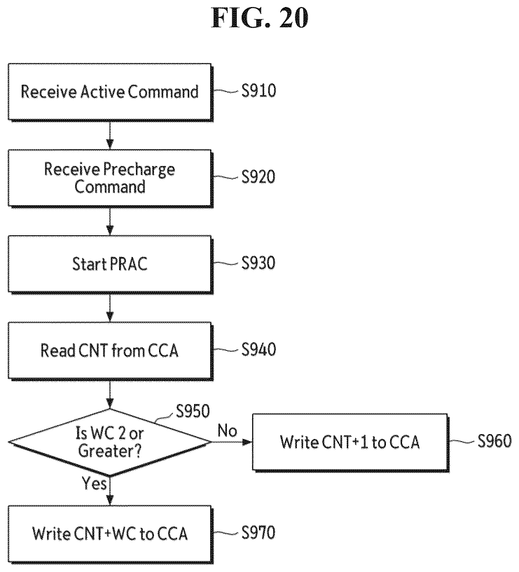

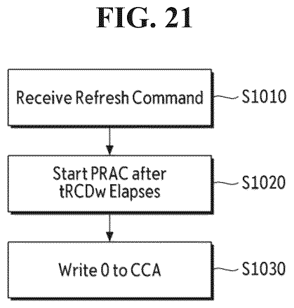

FIGS. 20 and 21 are flowcharts for explaining the operation of the memory device of FIG. 6.

Referring to FIGS. 6, 12, and 20, the memory device 20 may receive the active command ACT_CMD for the first wordline WL1 (S910). Then, the address signal BRA may be generated by the active command ACT_CMD. Through the fourth latch 3300, the address signal BRA may set the bank activation signal PRD.

After the lapse of the fourth period tRAS, the memory device 20 may receive the precharge command PRE_CMD for the first wordline WL1 (S920). The precharge address signal BPRA may be generated by the precharge command PRE_CMD.

The counting master signal PRAC_MST may be output through the fifth latch 3700, the AND gate 3750, and the first multiplexer 3800 of the count logic 300 that have received the precharge address signal BPRA and the bank activation signal PRD.

Accordingly, a counting operation may be performed (S930). The counting operation may include per row activation counting (PRAC). The counting operation may be performed by the updater 3900. The counting operation in response to the active command ACT_CMD and the precharge command PRE_CMD may include an update operation. For example, the updater 3900 may start PRAC in response to the active command ACT_CMD.

Specifically, the updater 3900 may read the count values CNT stored in the count cell array CCA of FIG. 4 (S940). For example, according to the active command ACT_CMD and the precharge command PRE_CMD for the first wordline WL1, the count values CNT stored in the count cells (e.g., CC11 through CC1m of FIG. 4) connected to the first wordline WL1 may be read.

Then, the updater 3900 determines whether the weighted count value WC is 2 or greater (S950).

If the weighted count value WC is less than 2 (No), new count values CNT obtained by adding 1 to the read count values CNT may be written to the count cell array CCA (e.g., count cells CC11 through CC1m of FIG. 4) connected to the first wordline WL1 (S960).

If the weighted count value WC is 2 or greater (Yes), new count values CNT obtained by adding the weighted count value WC to the read count values CNT may be written to the count cell array CCA (e.g., count cells CC11 through CC1m of FIG. 4) connected to the first wordline WL1 (S970).

Referring to FIGS. 6, 15, and 21, the memory device 20 may receive the refresh command REF_CMD for the first wordline WL1 (S1010).

Then, when the second period tRCDw has elapsed from the receipt of the refresh command REF_CMD, a counting operation may be performed (S1020). The counting operation may include PRAC. The counting operation may be performed by the updater 3900. The counting operation in response to the refresh command REF_CMD may include a reset operation.

Specifically, the address signal BRA and the paper signal PAPER may be generated by the refresh command REF_CMD. The third counter 3600 that has received the address signal BRA may output the delayed address signal BRA_RCDw after the lapse of the second period tRCDw. The first multiplexer 3800 may output the delayed address signal BRA_RCDw due to the paper signal PAPER, and the counting master signal PRAC_MST may be generated. The updater 3900 that has received the counting master signal PRAC_MST may perform the counting operation.

As previously mentioned, the counting operation performed in response to the refresh command REF_CMD does not require an additional refresh, and thus, the count values CNT can be reset regardless of the existing count values CNT. Therefore, the updater 3900 may write a value of 0 to the count cell array CCA (e.g., count cells CC11 through CC1m of FIG. 4) connected to the first wordline WL1 (S1030).

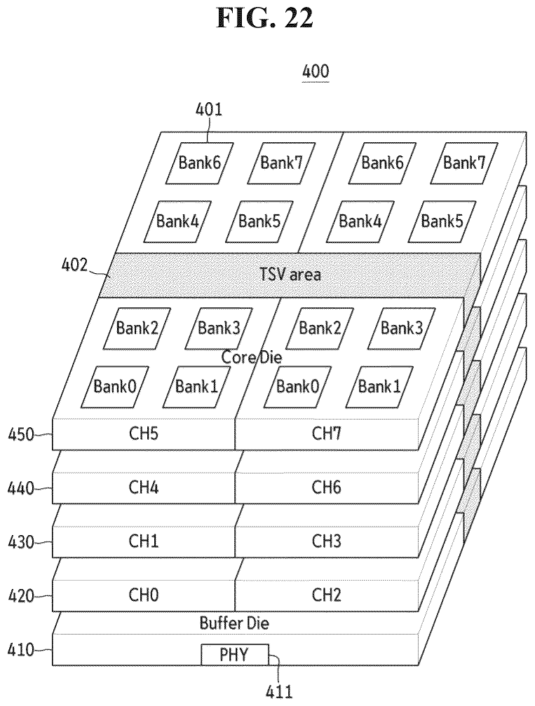

FIG. 22 is a block diagram illustrating a stacked memory device according to some example embodiments of the present disclosure. Referring to FIG. 22, a stacked memory device 400 may include a buffer die 410 and a plurality of core dies, for example, first, second, third, and fourth core dies 420, 430, 440, and 450. For example, the buffer die 410 may also be referred to as an interface die, base die, logic die, or master die, and the first, second, third, and fourth core dies 420, 430, 440, and 450 may also be referred to as memory dies or slave dies. FIG. 22 illustrates that the stacked memory device 400 includes four core dies, i.e., the first, second, third, and fourth core dies 420, 430, 440, and 450, but the number of core dies included in the stacked memory device 400 may vary. Additionally, the stacked memory device 400 may include 8, 12, or 16 core dies.

The buffer die 410 and the first, second, third, and fourth core dies 420, 430, 440, and 450 may be stacked and electrically connected through through-silicon vias (TSVs). Accordingly, the stacked memory device 400 may have a three-dimensional (3D) memory structure with the first, second, third, and fourth core dies 420, 430, 440, and 450 stacked therein. For example, the stacked memory device 400 may be implemented based on the High Bandwidth Memory (HBM) or Hybrid Memory Cube (HMC) standards.

The stacked memory device 400 may support multiple functionally independent channels (or vaults). For example, as illustrated in FIG. 22, the stacked memory device 400 may support eight channels, i.e., first through eighth channels CH0 through CH7. If each of the channels CH0 through CH7 supports 128 data (DQ) paths (I/O), the stacked memory device 400 may support 1024 data paths, but the present disclosure is not limited thereto. Alternatively, the stacked memory device 400 may support more than 1024 data paths and more than eight channels (e.g., 16 channels). If the stacked memory device 400 supports 16 channels, each of the 16 channels may support 64 data paths.

Each of the first, second, third, and fourth core dies 420, 430, 440, and 450 may support at least one channel. For example, as illustrated in FIG. 22, each of the core dies 420, 430, 440, and 450 may support two channels. Specifically, the first, second, third, and fourth core dies 420, 430, 440, and 450 may support the first and third channels CH0 and CH2, the second and fourth channels CH1 and CH3, the fifth and seventh channels CH4 and CH6, and the sixth and eighth channels CH5 and CH7, respectively. In this example, the first, second, third, and fourth core dies 420, 430, 440, and 450 may support different sets of channels, but the present disclosure is not limited thereto. Alternatively, at least two of the first, second, third, and fourth core dies 420, 430, 440, and 450 may support the same channel. For example, each of the first, second, third, and fourth core dies 420, 430, 440, and 450 may support the first channel CH0.

Each of the first through eighth channels CH0 through CH7 may configure an independent command and data interface. For example, the first through eighth channels CH0 through CH7 may be independently clocked based on independent timing requirements and may not be synchronized with one another. For example, the first through eighth channels CH0 through CH7 may change their power state or perform a refresh operation based on an independent command.

Each of the first through eighth channels CH0 through CH7 may include a plurality of bank memories 401 (e.g., bank memories Bank0 to Bank7). Each of the bank memories 401 may include memory cells connected to wordlines and bitlines (e.g., wordlines WL1 to WLn and bitlines BL1 to BLm of FIG. 4), row selection circuits (e.g., row selection circuit 250), column decoders (e.g., column decoder 270), sense amplifiers (e.g., sense amplifiers 285), etc. For example, as illustrated in FIG. 22, each of the first through eighth channels CH0 through CH7 may include eight bank memories 401, but the present invention is not limited thereto. Alternatively, each of the first through eighth channels CH0 through CH7 may include more than eight bank memories 401. FIG. 22 illustrates that the bank memories 401 included in one channel are included in one core die, but the bank memories 401 included in one channel may be distributed among multiple core dies. Alternatively, if each of the first, second, third, and fourth core dies 420, 430, 440, and 450 supports the first channel CH0, the bank memories 401 included in the first channel CH0 may be distributed among the first, second, third, and fourth core dies 420, 430, 440, and 450.

In some embodiments, a single channel may be divided into two pseudo channels that operate independently. For example, the pseudo channels may share the command and clock inputs of the channel (e.g., a clock signal CK and a clock enable signal CKE) but may decode and execute commands independently. For example, if a single channel supports 128 data paths, each pseudo channel may support 64 data paths. Alternatively, if a single channel supports 64 data paths, each pseudo channel may support 32 data paths.

The buffer die 410 and each of the first, second, third, and fourth core dies 420, 430, 440, and 450 may include a TSV area 402. TSVs configured to penetrate the first, second, third, and fourth core dies 420, 430, 440, and 450 may be arranged in the TSV area 402. Through the TSVs, the buffer die 410 may send and receive signals and/or data with the first, second, third, and fourth core dies 420, 430, 440, and 450. Each of the first, second, third, and fourth core dies 420, 430, 440, and 450 may also send and receive signals and/or data with the buffer die 410 and other core dies through the TSVs. In this case, signals and/or data can be independently transmitted and received through the TSVs corresponding to each of the first through eighth channels CH0 through CH7. For example, if an external host device sends commands and addresses through the first channel CH0 to access memory cells in the first core die 420, the buffer die 410 may transmit control signals to the first core die 420 through the TSVs corresponding to the first channel CH0, enabling access to the memory cells of the first channel CH0.

The buffer die 410 may include a physical layer (“PHY”) 411. The physical layer 411 may include interface circuits for communication with an external host device. For example, signals and/or data received through the physical layer 411 may be transmitted to the first, second, third, and fourth core dies 420, 430, 440, and 450 through the TSVs.

In some embodiments, the buffer die 410 may include a channel controller corresponding to each of the first through eighth channels CH0 through CH7. The channel controller may manage memory reference operations for the corresponding channels and determine the timing requirements for the corresponding channels.

In some embodiments, the buffer die 410 may include a plurality of pins for receiving signals from an external host device. The buffer die 410 may receive a clock signal CK, a command/address signal C/A, a write data strobe signal WDQS, and a data signal DQ and transmit a read data strobe signal RDQS and a data signal DQ through the plurality of pins. For example, the buffer die 410 may include 2 pins for receiving the clock signal CK, 14 pins for receiving the command/address signal C/A, 8 pins for receiving the write data strobe signal WDQS, 8 pins for transmitting the read data strobe signal RDQS, and 128 pins for transmitting and receiving the data signal DQ for each of the first through eighth channels CH0 through CH7.

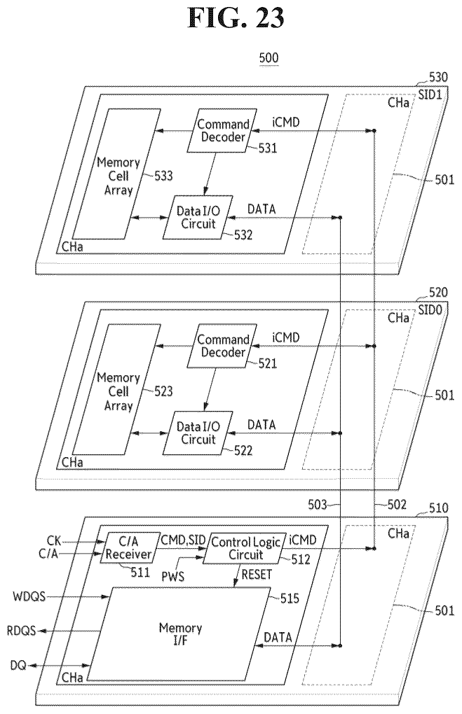

FIG. 23 is a block diagram of the stacked memory device of FIG. 22.

Referring to FIG. 23, a stacked memory device 500 may include a buffer die 510, a first core die 520, and a second core die 530. The first and second core dies 520 and 530 may support the same channel CHa among a plurality of channels. In this case, the first and second core dies 520 and 530 may be distinguished by stack identifiers (IDs). For example, the first core die 520 may correspond to a first stack ID SID0, and the second core die 530 may correspond to a second stack ID SID1. FIG. 23 illustrates that there exists no other core die between the first and second core dies 520 and 530, but other core dies may be positioned between the first and second core dies 520 and 530.

The buffer die 510 and the first and second core dies 520 and 530 may communicate through TSVs located in a TSV area 501. For example, the buffer die 510 may transmit an internal command iCMD to the first core die 520 and/or the second core die 530 through a TSV 502 and may send and receive data DATA with the first core die 520 and/or the second core die 530 through a TSV 503. FIG. 23 illustrates that the buffer die 510 communicates with the first and second core dies 520 and 530 using the same TSVs, but alternatively, the buffer die 510 may communicate with the first and second core dies 520 and 530 using different sets of TSVs.

The second core die 530 may include a command decoder 531, a data I/O circuit 532, and a memory cell array 533. The command decoder 531, the data I/O circuit 532, and the memory cell array 533 may operate substantially the same as the command decoder 521, the data I/O circuit 522, and the memory cell array 523 of the first core die 520.

The C/A receiver 511 may latch the command/address signal C/A based on the clock signal CK to receive a command CMD and a stack ID SID. The stack ID SID may be an address representing at least one core die to distinguish core dies supporting the same channel. The received command CMD and stack ID SID may be provided to the control logic circuit 512.

The control logic circuit 512 may transmit the internal command iCMD to at least one of the first and second core dies 520 and 530 based on the received stack ID SID. For example, if the received stack ID SID indicates the first SID SID0, the control logic circuit 512 may transmit the internal command iCMD to the first core die 520.

In some embodiments, as illustrated in FIG. 23, when the internal command iCMD and the data DATA are transmitted to the first and second core dies 520 and 530 through the common TSVs 502 and 503, the buffer die 510 may transmit the received stack ID SID to the first and second core dies 520 and 530. The first and second core dies 520 and 530 may decode the received stack ID SID to selectively receive the internal command iCMD and the data DATA. For example, if the received stack ID SID indicates the first stack ID SID0, the first core die 520 may receive the internal command iCMD and the data DATA transmitted through the TSVs 502 and 503. In this case, the second core die 530 may not receive the internal command iCMD and the data DATA transmitted through the TSVs 502 and 503.

Alternatively, in some embodiments, when the internal command iCMD and the data DATA are transmitted to the first and second core dies 520 and 530 through separate sets of TSVs, the buffer die 510 may transmit the internal command iCMD and the data DATA to the core die corresponding to the received stack ID SID through the corresponding set of TSVs.

As described above, when the first and second core dies 520 and 530 support the same channel CHa, the stacked memory device 500 may perform a write operation and a read operation according to an active command or a refresh operation according to a refresh command based on at least one of the first core die 520 and the second core die 530, as determined by the received stack ID SID.

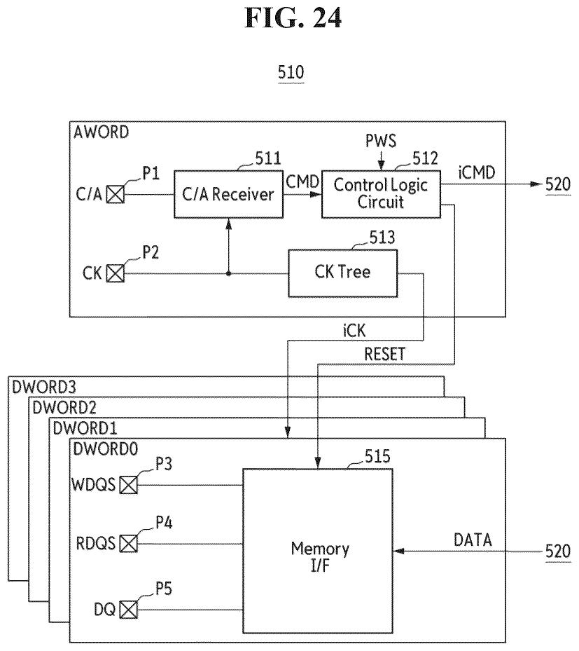

FIG. 24 is a block diagram illustrating an exemplary buffer die of FIG. 23.

Referring to FIG. 24, the buffer die 510 may include a command address input/output block AWORD and data I/O blocks DWORD0 through DWORD3.

FIG. 24 illustrates that the buffer die 510 includes four data input/output blocks DWORD0 through DWORD3, but the buffer die 510 may include various numbers of data I/O blocks. For example, the buffer die 510 may include two data I/O blocks.

The command address input/output block AWORD may include a C/A receiver 511, a control logic circuit 512, and a clock tree 516. The C/A receiver 511 may latch a command/address signal C/A received from a pad P1 based on the clock signal CK received from a pad P2 and may thereby receive a command CMD. The control logic circuit 512 may generate a reset signal RESET based on the command CMD or power state information PWS and transmit the reset signal RESET to each of the data I/O blocks DWORD0 through DWORD3. The control logic circuit 512 may generate an internal command iCMD according to the command CMD and transmit the internal command iCMD to the first core die 520. The clock tree 516 may be configured as an inverter chain including multiple inverters. The internal clock signal iCK generated from the clock signal CK through the clock tree 516 may be transmitted to each of the data I/O blocks DWORD0 through DWORD3.

Each of the data I/O blocks DWORD0 through DWORD3 may receive the internal clock signal iCK and the reset signal RESET from the command address I/O block AWORD. Each of the data I/O blocks DWORD0 through DWORD3 may include a memory device interface 515. The memory device interface 515 is connected to each of the first and second core dies 520 and 530. The memory device interface 515 may send and receive the write data strobe signal WDQS to the first and second core dies 520 and 530 via a pad P3, the read data strobe signal RDQS via a pad P4, and the data signal DQ via a pad P5.

As described above, the pad P2 receiving the clock signal CK is located in the command address I/O block AWORD, and the pads P3 and P4 receiving the write data strobe signal WDQS and the read data strobe signal RDQS may be located in the data I/O blocks DWORD. The clock signal CK received by the command address I/O block AWORD may be transmitted to the data I/O blocks DWORD through the clock tree (“CK Tree”) 513.

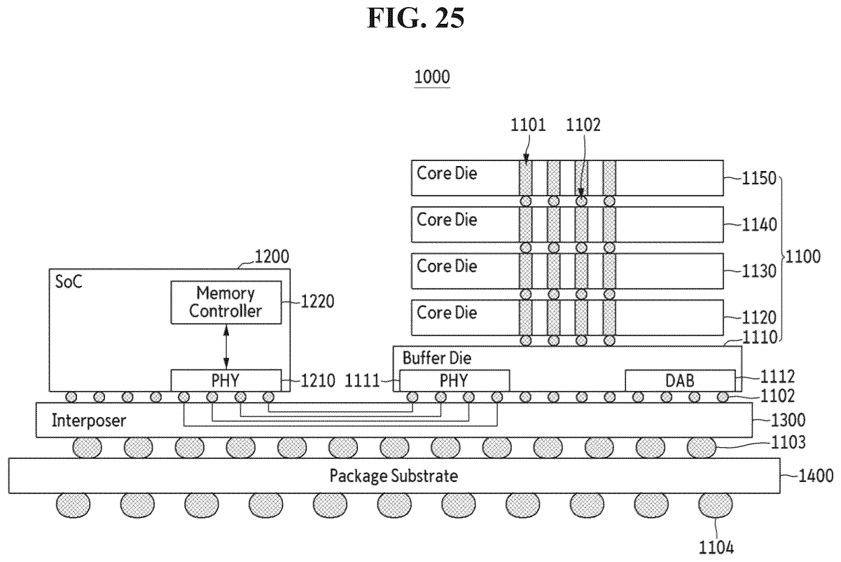

FIG. 25 is a diagram illustrating a semiconductor package according to some example embodiments of the present disclosure.

Referring to FIG. 25, a semiconductor package 1000 may include a stacked memory device 1100, a system-on-chip (SoC) 1200, an interposer 1300, and a package substrate 1400. The stacked memory device 1100 may include a buffer die 1110 and first, second, third, and fourth core dies 1120, 1130, 1140, and 1150. The buffer die 1110 may correspond to the buffer die 410 of FIG. 22, and the first, second, third, and fourth core dies 1120, 1130, 1140, and 1150 may correspond to the first, second, third, and fourth core dies 420, 430, 440, and 450, respectively, of FIG. 22.

Each of the first, second, third, and fourth core dies 1120 through 1150 may include a memory cell array. The buffer die 1110 may include a physical layer (“PHY”) 1111 and a direct access area (“DAB”) 1112. The physical layer 1111 may be electrically connected to the physical layer 1210 of the SoC 1200 through the interposer 1300. The stacked memory device 1100 may receive signals from or send signals to the SoC 1200 through the physical layer 1111. The physical layer 1111 may include interface circuits of the buffer die 510 described with reference to FIG. 23.

The direct access area 1112 may provide an access path to test the stacked memory device 1100 without passing through the SoC 1200. The direct access area 1112 may include conductive means (e.g., ports or pins) that can communicate directly with an external testing device. Test signals and data received through the direct access area 1112 may be transmitted to the first, second, third, and fourth core dies 1120, 1130, 1140, and 1150 via TSVs 1101. Data read from the first, second, third, and fourth core dies 1120, 1130, 1140, and 1150 for testing purposes may be transmitted to the testing device through both the TSVs 1101 and the direct access area 1112. Accordingly, direct-access testing of the first, second, third, and fourth core dies 1120, 1130, 1140, and 1150 can be performed.

The buffer die 1110 and the first, second, third, and fourth core dies 1120, 1130, 1140, and 1150 may be electrically connected to each other through TSVs 1101 and bumps 1102. The buffer die 1110 may receive signals provided to each channel from the SoC 1200 through bumps 1102 allocated to each channel. For example, the bumps 1102 may be micro-bumps.

The SoC 1200 may execute applications supported by the semiconductor package 1000 using the stacked memory device 1100. For example, the SoC 1200 may include at least one processor from among a Central Processing Unit (CPU), an Application Processor (AP), a Graphics Processing Unit (GPU), a Neural Processing Unit (NPU), a Tensor Processing Unit (TPU), a Vision Processing Unit (VPU), an Image Signal Processor (ISP), and a Digital Signal Processor (DSP) to perform specialized operations.

The SoC 1200 may include a physical layer (“PHY”) 1210 and a memory controller 1220. The physical layer 1210 may include I/O circuits for transmitting and receiving signals with the physical layer 1111 of the stacked memory device 1100. The SoC 1200 may provide various signals to the physical layer 1111 through the physical layer 1210. The signals provided to the physical layer 1111 may be delivered to the first, second, third, and fourth core dies 1120, 1130, 1140, and 1150 through the interface circuits of the physical layer 1111 and the TSVs 1101.

The memory controller 1220 may control the overall operation of the stacked memory device 1100. The memory controller 1220 may transmit signals to control the stacked memory device 1100 through the physical layer 1210. The memory controller 1220 may correspond to the memory controller 10 of FIG. 1.

The interposer 1300 may connect the stacked memory device 1100 and the SoC 1200. The interposer 1300 may connect the physical layer 1111 of the stacked memory device 1100 and the physical layer 1210 of the SoC 1200 and provide physical paths formed using conductive materials. Accordingly, the stacked memory device 1100 and the SoC 1200 can be stacked on the interposer 1300 to transmit signals to and receive signals from each other.

Bumps 1103 may be attached to the upper part of the package substrate 1400, and solder balls 1104 may be attached to the lower part of the package substrate 1400. For example, the bumps 1103 may be flip-chip bumps. The interposer 1300 may be stacked on the package substrate 1400 through the bumps 1103. The semiconductor package 1000 may transmit and receive signals with other external packages or semiconductor devices through the solder balls 1104. For example, the package substrate 1400 may be a printed circuit board (PCB).

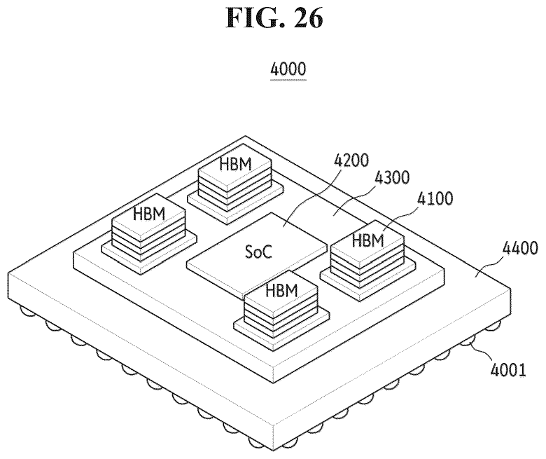

FIG. 26 is a diagram illustrating an exemplary implementation of a semiconductor package according to an example embodiment of the present disclosure.

Referring to FIG. 26, a semiconductor package 4000 may include a plurality of stacked memory devices 4100 and an SoC 4200. The stacked memory devices 4100 and the SoC 4200 may be stacked on an interposer 4300, and the interposer 4300 may be stacked on a package substrate 4400. The semiconductor package 4000 may transmit and receive signals with other external packages or semiconductor devices through solder balls 4001 attached to the bottom of the package substrate 4400.

The stacked memory devices 4100 may be implemented based on the HBM standard, but the present disclosure is not limited thereto. Alternatively, the stacked memory devices 4100 may be implemented based on the GDDR, HMC, or Wide I/O standard. The stacked memory devices 4100 may correspond to the stacked memory devices 400, 500, and 1100 of FIGS. 22 through 25.

The SoC 4200 may include at least one processor from among a CPU, an AP, a GPU, and an NPU, and a plurality of memory controllers for controlling the multiple stacked memory devices 4100. The SoC 4200 may transmit and receive signals with the corresponding stacked memory device through a memory controller. The SoC 4200 may correspond to the SoC 1200 of FIG. 25.

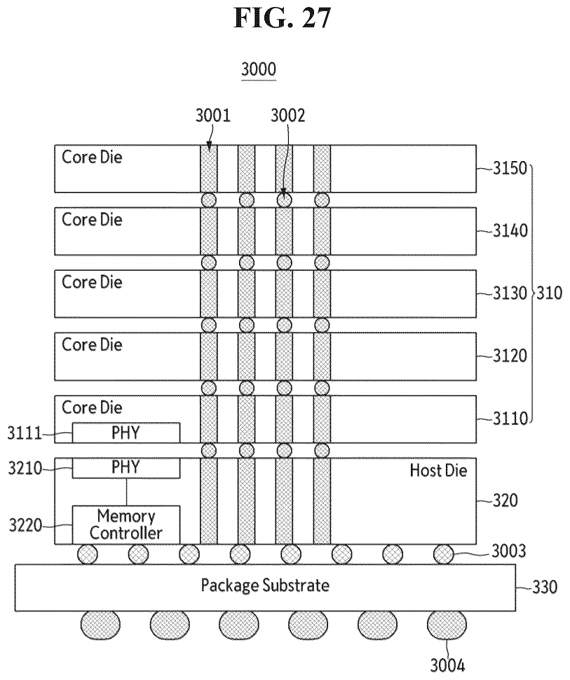

FIG. 27 is a diagram illustrating a semiconductor package according to some example embodiments of the present disclosure.

Referring to FIG. 27, a semiconductor package 3000 may include a stacked memory device 310, a host die 320, and a package substrate 330. The stacked memory device 310 may include a buffer die 3110 and first, second, third, and fourth core dies 3120, 3130, 3140, and 3150. The buffer die 3110 may include a physical layer (“PHY”) 3111 for communication with the host die 320, and each of the first, second, third, and fourth core dies 3120, 3130, 3140, and 3150 may include a memory cell array. The stacked memory device 310 may correspond to the stacked memory devices 400 and 500 of FIGS. 22 and 23.

The host die 320 may include a physical layer (“PHY”) 3210 for communication with the stacked memory device 310 and a memory controller 3220 for controlling the overall operation of the stacked memory device 310. Additionally, the host die 320 may include a processor for controlling the overall operation of the semiconductor package 3000 and execute applications supported by the semiconductor package 3000. For example, the host die 320 may include at least one processor from among a CPU, an AP, a GPU, and an NPU.

The stacked memory device 310 may be disposed on the host die 320 based on TSVs 3001 and may be vertically stacked on the host die 320. Accordingly, the buffer die 3110, the first, second, third, and fourth core dies 3120, 3130, 3140, and 3150, and the host die 320 may be electrically connected to one another through the TSVs 3001 and bumps 3002 without an interposer. For example, the bumps 3002 may be micro-bumps.

Bumps 3003 may be attached to the upper part of the package substrate 330, and solder balls 3004 may be attached to the lower part of the package substrate 330. For example, the bumps 3003 may be flip-chip bumps. The host die 320 may be stacked on the package substrate 330 through the bumps 3003. The semiconductor package 3000 may transmit and receive signals with other external packages or semiconductor devices through the solder balls 3004.

Alternatively, in some embodiments, the stacked memory device 310 may be implemented with only the first, second, third, and fourth core dies 3120, 3130, 3140, and 3150 without the buffer die 3110. In this case, each of the first, second, third, and fourth core dies 3120, 3130, 3140, and 3150 may include interface circuits for communication with the host die 320. Each of the first, second, third, and fourth core dies 3120, 3130, 3140, and 3150 may transmit and receive signals with the host die 320 through the TSVs 3001.

As described above, although the embodiments of the present disclosure have been described with reference to the accompanying drawings, the present disclosure is not limited to these embodiments and may be embodied in various forms. Those skilled in the art will appreciate that various modifications and changes can be made without departing from the technical spirit or essential characteristics of the present disclosure. Therefore, the above-described embodiments are to be understood as illustrative and not restrictive in all aspects.

1. A memory device comprising:
a memory cell array including a wordline;
master signal logic configured to generate a first address signal in response to the wordline being selected based on a refresh command or an active command, and to generate a second address signal in response to the wordline being selected based on a precharge command; and
count logic configured to reset a count value of a count cell connected to the wordline based on a paper signal generated in response to the wordline being selected based on the first address signal and the refresh command, and to read and then update the count value of the count cell based on the second address signal.

2. The memory device of claim 1, wherein the count logic includes:
a first circuit configured to determine whether to perform a precharge operation based on the second address signal;
a second circuit configured to generate a first signal to reset the count value of the count cell based on the first address signal; and
a third circuit configured to generate a second signal to update the count value of the count cell based on the second address signal and an output signal of the first circuit.

3. The memory device of claim 2, wherein the first signal is generated in response to a lapse of a first period after the generation of the first address signal.

4. The memory device of claim 2, wherein the resetting of the count value of the count cell includes writing a value corresponding to 0 to the count cell connected to the wordline.

5. The memory device of claim 2, wherein updating the count value of the count cell includes reading a first count value of the count cell connected to the wordline, and writing a second count value, obtained by adding an update value to the first count value, to the count cell.

6. The memory device of claim 5, wherein the update value is 1.

7. The memory device of claim 5, wherein the update value is obtained by dividing a period between the active command and the precharge command by a minimum required period between the active command and the precharge command.

8. The memory device of claim 2,
wherein the count logic further includes a multiplexer configured to receive output signals of the second and third circuits, and
wherein the multiplexer is configured to output the first signal in response to the paper signal being at a first logic level, and output the second signal in response to the paper signal being at a second logic level different from the first logic level.

9. The memory device of claim 1, wherein the master signal logic is configured to:
generate an internal precharge signal in response to a lapse of a first period after the selection of the wordline based on the precharge command; and
generate the second address signal in response to the internal precharge signal.

10. The memory device of claim 1, further comprising:
a bank controller configured to control the memory cell array; and
a pad configured to provide command and address signals to the bank controller,
wherein the pad includes the master signal logic, and
wherein the bank controller includes the count logic.

11. A memory device comprising:
a memory cell array including a wordline;
a multiplexer configured to receive a paper signal having a first logic level in response to the wordline being selected based on a refresh command, and output a first signal in response to receiving the paper signal having the first logic level, and to receive a paper signal having a second logic level different from the first logic level in response to the wordline being selected based on an active command, and output a second signal; and
an updater configured to reset a count value of a count cell connected to the wordline in response to receipt of the first signal, and to update the count value of the count cell in response to receipt of the second signal,
wherein the first signal is generated based on a first address signal having the first logic level in response to the wordline being selected based on the refresh command or the active command,
wherein the first signal has the first logic level after a lapse of a first period from a transition of the first address signal to the first logic level,
wherein the second signal is generated based on a bank activation signal and a second address signal,
wherein the bank activation signal has the first logic level in response to the wordline being selected based on the refresh command or the active command, and
wherein the second address signal has the first logic level in response to the wordline being selected based on a precharge command.

12. The memory device of claim 11, wherein the multiplexer is configured to output the first signal in response to the paper signal indicating that a refresh operation is being performed on the wordline and having the first logic level, and output the second signal in response to the paper signal having the second logic level different from the first logic level.

13. The memory device of claim 12,
wherein the second signal is output through a logical AND operation on the second address signal and a third signal, and
wherein the third signal is set to the second logic level in response to the second address signal having the first logic level, and is reset to the first logic level in response to the bank activation signal having the second logic level.

14. The memory device of claim 11, wherein the bank activation signal is output from a latch circuit that receives the first address signal as a set signal and receives an output signal of a first circuit as a reset signal.

15. The memory device of claim 14,
wherein the first circuit includes a counter and a second multiplexer,
wherein the counter is triggered by the second address signal and is configured to output a third address signal generated based on the second address signal, and
wherein the second multiplexer is configured to output the second address signal or the third address signal as the output signal of the first circuit based on a logic level of the paper signal indicating that a refresh operation is being performed on the wordline.

16. The memory device of claim 15,
wherein the second address signal is output in response to the paper signal having the first logic level, and
wherein the third address signal is output in response to the paper signal having the second logic level different from the first logic level.

17. The memory device of claim 11,
wherein the second address signal is generated based on a first sub-address signal or a second sub-address signal, and
wherein the first sub-address signal is generated after a lapse of a second period in response to a timer circuit receiving the refresh command.

18. The memory device of claim 17,
wherein the second sub-address signal is generated based on a precharge command or an internal precharge signal, and
wherein the internal precharge signal is generated after a signal generated by the precharge command is input to the timer circuit and the timer circuit counts a third period.

19. The memory device of claim 11,
wherein the precharge command is received after a lapse of a second period from the receipt of the active command, and
wherein the first period is shorter than the second period.

20. An operating method of a memory device, comprising:
in response to receipt of an active command for a wordline, transitioning a first address signal representing an address of the wordline to a first logic level;
in response to the transition of the first address signal to the first logic level, transitioning a first signal indicating that a bank for the wordline is being activated to the first logic level;
in response to receipt of a precharge command for the wordline after a lapse of a first period from the receipt of the active command, performing a first transition that transitions a second address signal representing the address of the wordline to the first logic level;
in response to the first transition, reading a first count value of a count cell included in the wordline;
writing a second count value obtained by adding an update value to the first count value to the count cell;
generating a second signal for controlling a precharge operation for the wordline after a lapse of a second period from the receipt of the precharge command;
in response to the generation of the second signal, performing a second transition that transitions the second address signal to the first logic level; and
in response to the second transition, transitioning the first signal to a second logic level different from the first logic level.
